(19) United States
(12) Patent Application Publication
(10) Pub. No.: US 2014/0028686 A1
(43) Pub. Date: Jan. 30, 2014

(54) DISPLAY SYSTEM WITH THIN FILM ENCAPSULATED INVERTED IMOD

(71) Applicants: Rihui He, San Jose, CA (US); Marek Mienko, San Jose, CA (US); Alok Govil, Santa Clara, CA (US); Tsongming Kao, Sunnyvale, CA (US)

(72) Inventors: Rihui He, San Jose, CA (US); Marek Mienko, San Jose, CA (US); Alok Govil, Santa Clara, CA (US); Tsongming Kao, Sunnyvale, CA (US)

(73) Assignee: QUALCOMM MEMS TECHNOLOGIES, INC., San Diego, CA (US)

(21) Appl. No.: 13/560,732

(22) Filed: Jul. 27, 2012

(51) Int. Cl. G06T 1/00; H01L 33/60; G02B 26/00

(52) U.S. Cl. 345/501; 359/291; 438/23; 257/E33.072

(57) ABSTRACT

This disclosure provides systems, methods and apparatus for encapsulating a display device. In one aspect, an interferometric modulator (IMOD) is formed on a substrate. The IMOD includes an absorbing layer separated from the substrate, a reflective layer between the absorbing layer and the substrate, and an optical gap between the absorbing layer and the reflective layer. One or more thin film encapsulation layers hermetically seal the IMOD between the one or more thin film encapsulation layers and the substrate. In another aspect, an optical or functional layer can be formed over the one or more thin film encapsulation layers.

### TECHNICAL FIELD

This disclosure relates generally to electromechanical systems (EMS) devices and more particularly to encapsulated inverted IMODs and methods for fabricating the same.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

An IMOD or other EMS device may be packed to protect it from the environment and from operational hazards, such as mechanical shock.

### SUMMARY

The systems, methods and devices of the disclosure each have several innovative aspects, no single one of which is solely responsible for the desirable attributes disclosed herein.

One innovative aspect of the subject matter described in this disclosure can be implemented in a display. The display includes a substrate and an array of interferometric modulators (IMODs) formed on the substrate. Each IMOD includes an absorbing layer separated from the substrate, a reflective layer between the substrate and the absorbing layer, and an optical gap between the absorbing layer and the reflective layer. The display further includes one or more thin film encapsulation layers hermetically sealing each IMOD between the one or more thin film encapsulation layers and the substrate, where the one or more thin film encapsulation layers includes a transparent layer.

In some implementations, the display has a display side for viewing the display and a rear side opposite the display side, where the one or more thin film encapsulation layers are on the display side of the array of IMODs. In some implementations, the substrate includes a plurality of thin film transistors. In some implementations, the display includes an optical adhesive layer on the one or more thin film encapsulation layers. In some implementations, the display includes a functional layer over the one or more thin film encapsulation layers. In some implementations, the one or more thin film encapsulation layers can include a shell layer and a sealing layer, where the shell layer is disposed between the absorbing layer of each IMOD and the sealing layer.

Another innovative aspect of the subject matter described in this disclosure can be implemented in a method of forming a display system. The method includes providing a substrate, forming a reflective layer over the substrate, and forming an absorber layer over and spaced apart from the reflective layer to define an optical gap between the absorber layer and the reflective layer. The method further includes depositing one or more thin film encapsulation layers over the absorber layer, where the one or more thin film encapsulation layers hermetically seal the reflective layer and the absorber layer between the one or more thin film encapsulation layers and the substrate.

In some implementations, the method further includes forming one or more thin film transistors on the substrate before forming the reflective layer over the substrate. In some implementations, the one or more thin film encapsulation layers can include a transparent layer. In some implementations, the method further includes forming a sensor on one of the substrate and the one or more thin film encapsulation layers. In some implementations, the method further includes forming an optical adhesive layer over the one or more thin film encapsulation layers. The method can further include laminating a transparent superstrate on the optical adhesive layer.

Another innovative aspect of the subject matter described in this disclosure can be implemented in a display system. The display system includes an array of interferometric modulators (IMODs) formed on a substrate. Each IMOD includes an absorbing layer separated from the substrate, a reflective layer between the substrate and the absorbing layer, and an optical gap defined between the absorbing layer and the reflective layer. The display system further includes a functional layer over the IMOD array. The display system further includes means for encapsulating each IMOD in the array, the encapsulating means hermetically sealing each IMOD between the substrate and the encapsulating means. The encapsulating means is between the functional layer and each IMOD in the array, and includes a means for transmitting light.

In some implementations, the encapsulating means has a thickness between about 1 μm and about 5 μm. In some implementations, display system further includes a means for adhering the functional layer and the encapsulating means.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a cross-sectional side view of a display device with a thin film encapsulation layer.

FIG. 10A shows an example of an enlarged cross-sectional side view of the display device of FIG. 9 in an unactuated state.

FIG. 10B shows an example of an enlarged cross-sectional side view of the display device of FIG. 9 in an actuated state.

FIG. 11 shows an example of a flow diagram illustrating a method of manufacturing of a display device.

FIGS. 12A-12E show examples of cross-sectional views illustrating various stages of manufacturing a display device.

FIGS. 13A and 13B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein relate to encapsulation of electromechanical systems devices, including IMODs. One or more thin film encapsulation layers can hermetically seal an IMOD between the one or more thin film encapsulation layers and a substrate upon which the IMOD is formed. In some implementations, the IMOD can be manufactured such that the display side (the side from which images can be viewed) of the IMOD is opposite the substrate. This means that reflected light from the IMOD pixels does not pass through the substrate to reach, for example, a viewer. Such an IMOD can be referred to as a “reverse IMOD” or an “inverted IMOD.” In some implementations, the inverted IMOD can include an absorbing layer separated from the substrate, a reflective layer between the absorbing layer and the substrate, and an optical gap defined between the absorbing layer and the reflective layer. In some implementations, an optical adhesive layer can be formed over the one or more thin film encapsulation layers.

Some implementations described herein relate to a method of manufacturing a display system. The method can involve providing a substrate, forming a reflective layer over the substrate and forming an absorber layer over and spaced apart from the reflective layer to define an optical gap between the absorber layer and the reflective layer. One or more thin film encapsulation layers can hermetically seal the reflective layer and the absorber layer between the one or more thin film encapsulation layers and the substrate.

Particular implementations of the subject matter described in this disclosure can be implemented to realize one or more of the following potential advantages. Forming a thin film encapsulation layer over an IMOD can encapsulate the device in a hermetic environment. A hermetic environment can improve the performance and operational lifetime of an IMOD by protecting it from components in the atmosphere, including water vapor, which can cause stiction. In some implementations, thin film encapsulation of an inverted IMOD can eliminate the need for a recessed glass over the inverted IMOD. This can improve optical performance by eliminating the air gap typically formed between a recessed glass and an inverted IMOD. In addition, a hermetic seal can be provided without using desiccants. Since desiccants are often placed on the edge of a back glass, thin film encapsulation which reduces or eliminates the need of desiccants can help achieve a reduced border size compared to MEMS devices that are macro-encapsulated. Moreover, the form factor can be improved. Furthermore, thin film encapsulation of an inverted IMOD can more easily integrate additional components such as sensors, transistors, diffusers, anti-reflective coatings, optical grade adhesives, and a functional layer on top of the thin film encapsulation layer. Ease of integration of such components with active matrix driving circuits in an IMOD display can improve the display scan rate for a video display.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

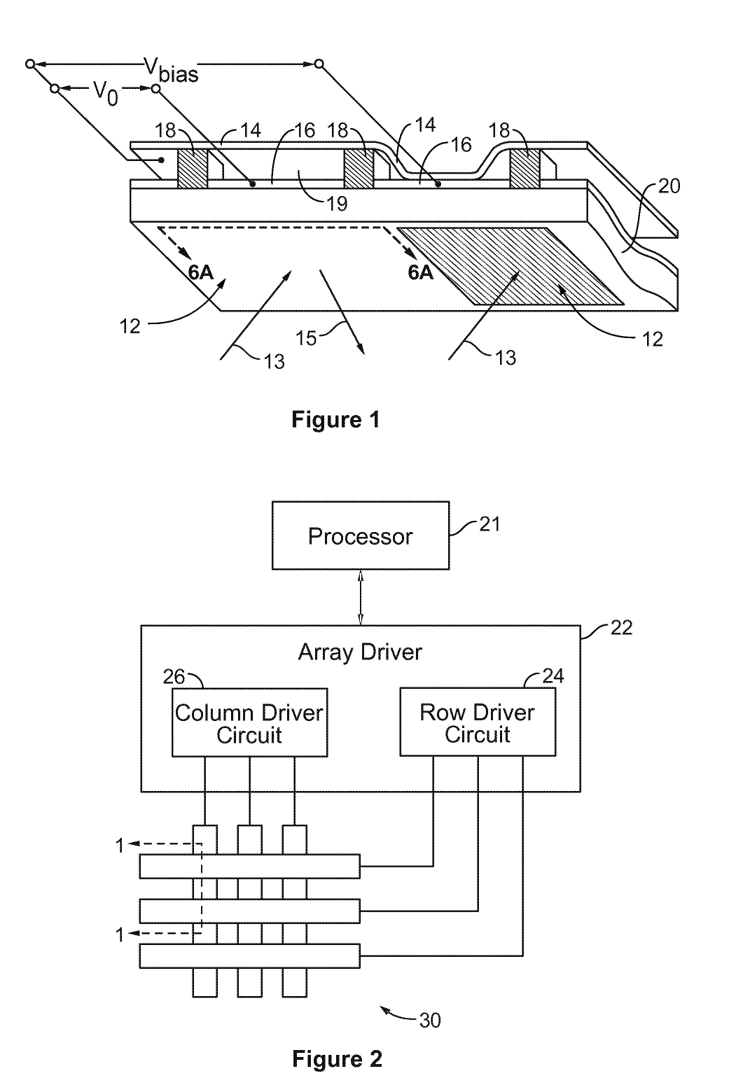

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

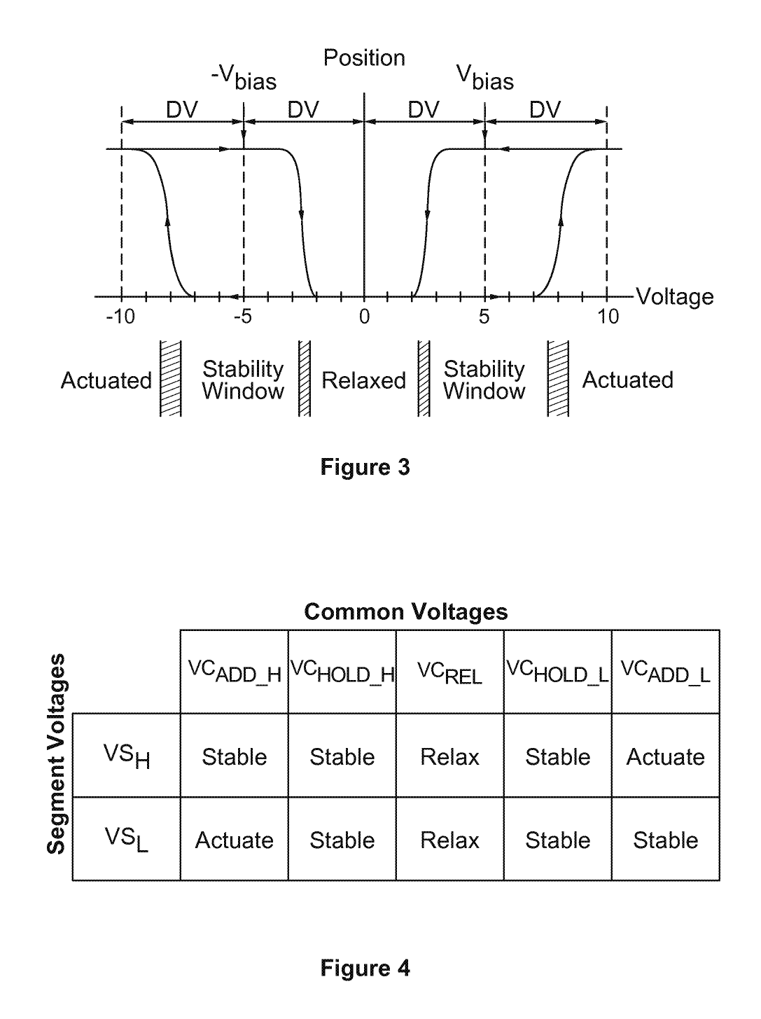

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

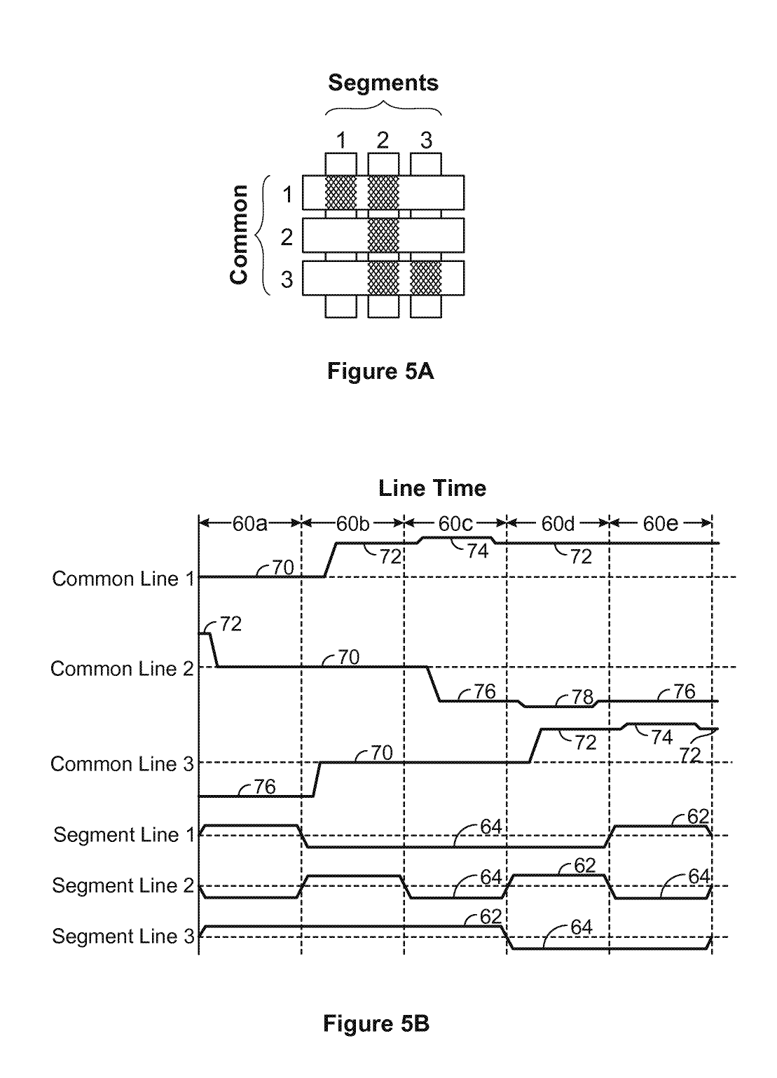

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

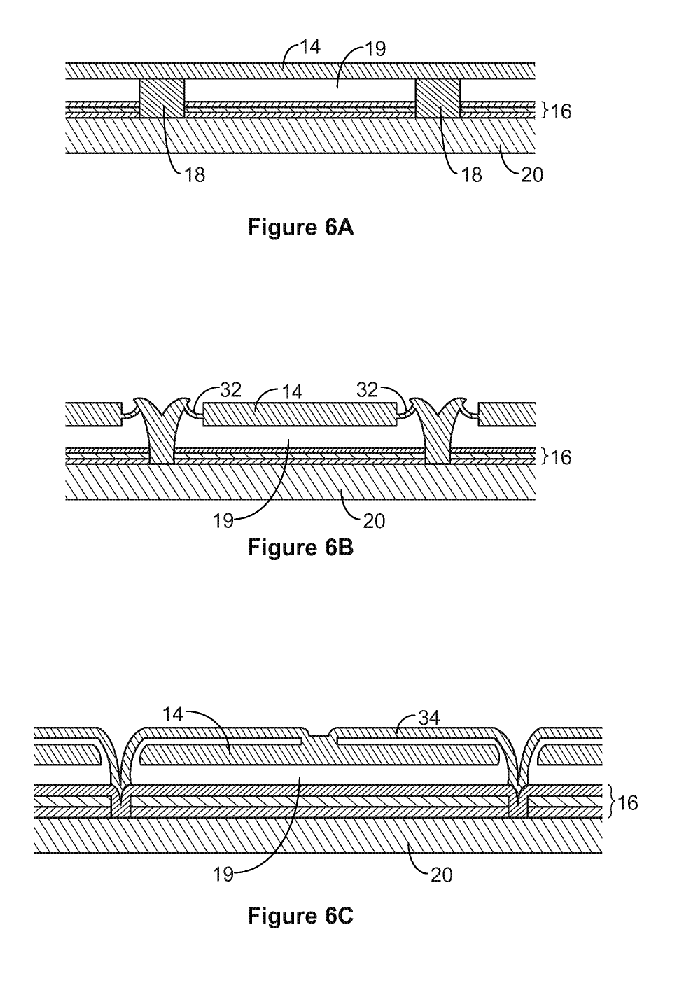

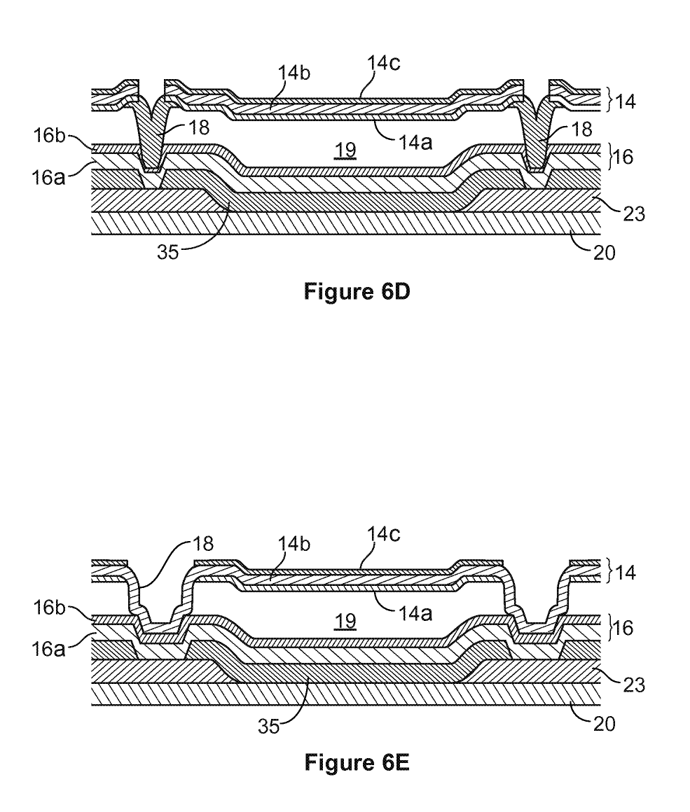

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

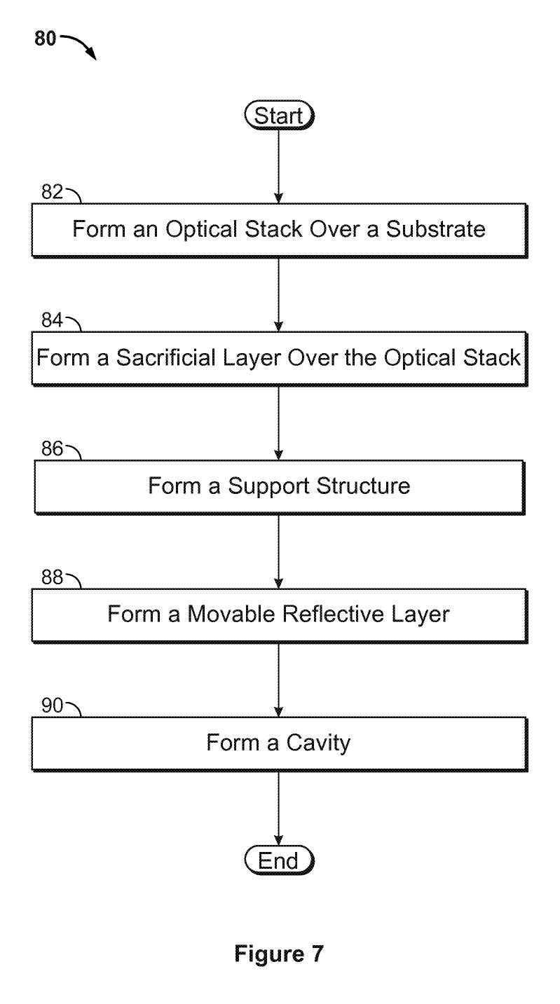

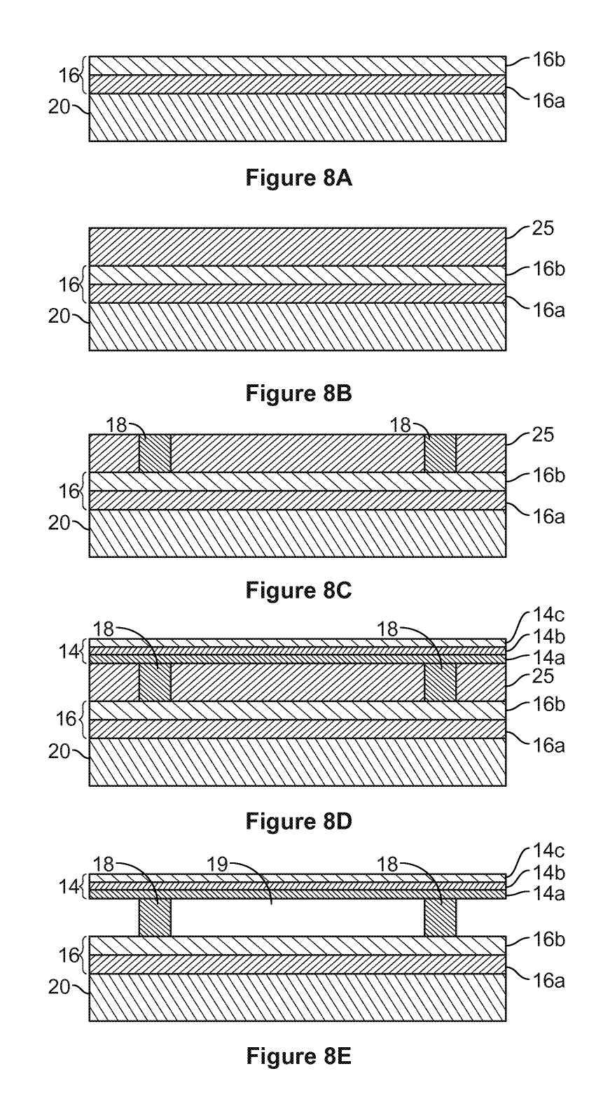

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Electromechanical systems devices, such as those shown in FIGS. 6A-6E, can be encapsulated to protect the electromechanical systems devices from environmental hazards, such as moisture and physical damage due to touch. Encapsulation techniques can include macro-encapsulation and thin film encapsulation. A thin film encapsulation process can involve depositing one or more thin film layers over the EMS device, while macro-encapsulation involves joining and/or bonding a cover to a device provided on a substrate to form a package. In some implementations, a thin film encapsulation layer can function as a substrate for additional circuit elements or layers formed above the thin film encapsulation layer.

In some implementations, thin film encapsulation layers can protect the EMS device from the environment by providing a hermetic seal. A hermetic seal has the quality of being substantially airtight and is substantially impervious to air, including water vapor and other gases in the air. Hermetic seals may serve to improve the performance and operational lifetimes of some EMS devices. For example, IMODs can include surfaces and/or parts that may come in and out of contact with one another. Adhesion of two separated layers of material to one another when the two layers come into contact with one another is called stiction. Stiction in IMODs may be exacerbated by water vapor in the air. Thus, hermetic seals that serve to protect an IMOD from water vapor can improve the performance and operational lifetime of the IMOD.

One type of IMOD is an inverted IMOD, which can also be referred to as a reverse IMOD. Reflected light from an inverted IMOD can be viewed so that the IMOD is disposed between a substrate and a viewer. In some implementations, the inverted IMOD can be encapsulated by one or more thin film encapsulation layers. The architecture for inverted IMODs can include designs that decouple the electromechanical performance of an IMOD from its optical performance. Examples of inverted IMOD structures are described in U.S. Pat. No. 6,674,562 and U.S. Pat. No. 7,564,612, which are incorporated herein by reference. Inverted IMODs that decouple the IMOD's electromechanical behavior from the IMOD's optical behavior allow the structural design and materials used for certain components to be selected independently of their optical properties. While implementations of the methods of thin film encapsulation and the resulting encapsulated devices are described chiefly in the context of packaging of inverted IMODs, the methods and packages are not so limited and may be implemented for packaging of other types of devices or structures, including any type of display element that can be viewed from a side opposite that of the substrate on which the display is fabricated.

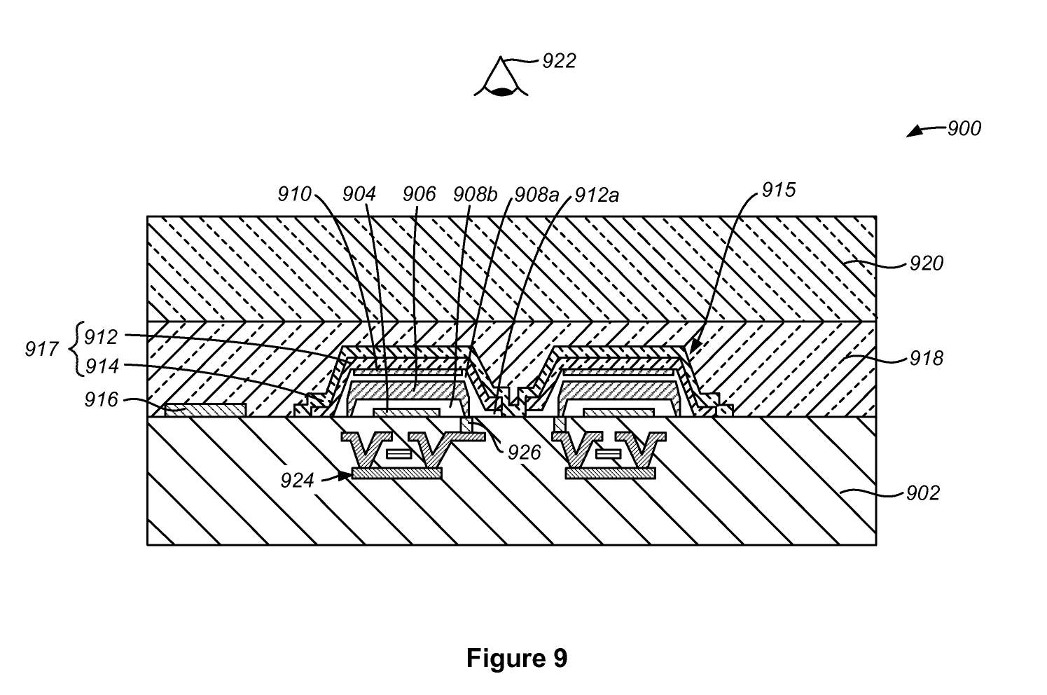

FIG. 9 shows an example of a cross-sectional side view of a display device with a thin film encapsulation layer. The display device 900 includes a transparent viewing layer 920 and a plurality of inverted IMOD pixels and a sensor 916 on a substrate 902. Two adjacent inverted IMOD pixels of the plurality of inverted IMOD pixels are depicted in FIG. 9, with each inverted IMOD pixel including an inverted IMOD 915. In some implementations, the plurality of inverted IMOD pixels can be arranged in an array. The display device 900 can have a display side and a rear side opposite the display side. Images from the display device 900 can be viewed from the display side. In some implementations, the display side can be opposite the substrate 902. In other words, unlike the direct-view devices described above with respect to FIGS. 6A-6E, reflected light from the IMOD pixels passes through the viewing layer 920 and not the substrate 902 to reach, for example, a viewer 922.

The substrate 902 that can include any number of different substrate materials. Because reflected light from the IMOD pixels does not pass through the substrate 902 to reach the viewer 922 in an inverted IMOD structure, the substrate 902 can include opaque and translucent materials, as well as transparent materials. In some implementations, opaque or translucent materials can have superior structural properties relative to transparent materials. Examples of materials that the substrate 902 can be made of can include metals, anodized metals, Si, polysilicon (poly-Si), silicon-on-insulator (SOI), plastics, ceramics, polymers, glass, spin-on glass, quartz, alloys, and composites. In some implementations, the substrate 902 can include a flexible plastic or metal foil with sufficient flexibility for roll-to-roll or web processing. Electronic circuitry such as sensors, transistors, resistors, and capacitors can be formed on the substrate 902.

The inverted IMOD 915 can have a display side that is opposite the substrate 902, as discussed earlier herein. The inverted IMOD 915 can include an absorbing layer 910 separated from the substrate 902, a reflective layer 906 between the substrate 902 and the absorbing layer 910, and an optical gap 908a between the absorbing layer 910 and the reflective layer 906. The inverted IMOD 915 can also include an electrode 904. In some implementations, the absorbing layer 910 can be stationary and the reflective layer 906 can be movable. Alternatively, in some other implementations, the absorbing layer 910 can be movable and the reflective layer 906 can be stationary. In some implementations, the inverted IMOD 915 can include a shell layer 912 over the absorbing layer 910, which can provide mechanical support for subsequent layers formed over the inverted IMOD 915. In the example of FIG. 9, the shell layer 912 also supports the absorbing layer 910. In some other implementations, the absorbing layer 910 can be free of any mechanical support layer supporting it from above, supported by posts or otherwise supported. For example, in some such implementations, the absorbing layer 910 can be movable.

In some implementations, the substrate 902 can include one or more thin film transistors (TFTs) in electrical communication with the inverted IMOD pixels. In the example of FIG. 9, a TFT 924 is depicted within the substrate 902. It is understood, however, that the TFT 924 can be formed on any part of the substrate 902, such as on the same side of the inverted IMOD pixels or on the backside of the substrate 902. In some implementations, each of the inverted IMOD pixels can be in electrical communication with one or more corresponding TFTs, each of which can be formed on a planarized layer (not shown) or surface on the substrate 902. The planarization layer can be between the substrate 902 and the inverted IMOD 915. For example, the substrate 902, TFTs 924, and the planarization layer together form a substrate for the IMOD pixels. In some implementations, the TFT 924 can be formed on a backside of the substrate 902 away from the viewing layer 920. A via 926 provides a conductive pathway through the substrate 902 to electrically connect the TFT 924 with the inverted IMOD 915.

In some implementations, one or more TFTs 924 can be formed underneath corresponding inverted IMOD pixels. The TFTs 924 can be formed with the planarization layer, and the inverted IMOD pixels would be formed on the planarization layer. In such implementations, a TFT can be arranged not to interfere with the operation of the inverted IMOD. For example, TFTs with the necessary routing from row and column drivers for driving scan lines and data lines, may be formed on the substrate 902. The inverted IMOD pixels may then be formed over the TFTs 924. In some implementations, a planarization or passivation layer may be formed over the TFTs 924, patterned with appropriate via holes for electrical connection, and the IMODs 915 may then be formed over the planarization or passivation layer.

The TFTs 924 can be formed before or after the IMODs 915 are formed on the substrate 902. In some implementations (not shown), one or more TFTs 924 can be formed on another substrate in a stack with the substrate 902. In some implementations (also not shown), one or more TFTs 924 can be formed over thin film encapsulation layers between the inverted IMOD pixels. Routing lines and vias can be used to electrically connect the TFTs to the inverted IMOD pixels.

While the drive schemes discussed above in relation to FIGS. 2-5B relate to passive matrix drive schemes that do not rely on switches, in some implementations, the display device 900 can be an active matrix display. Each of the inverted IMOD pixels can be connected to and configured to be individually addressed by a switching device. In some implementations, for example, the TFT 924 can be a switching device. The display device 900 can include a plurality of such TFTs 924, each of which is configured to address a single inverted IMOD pixel. Each IMOD pixel is then addressed through the TFT 924. For example, in some implementations, a data line may connect all of the source electrodes of the TFT 924 along a single column, while a scan line (often referred to as COM lines or enable lines) may connect all of the gates along a single row. The reflector 906 in the IMOD pixel may then be connected to the drain of the TFT 924, as illustrated, or alternatively, the drain of the TFT 924 may be connected to the electrode 904. The other of the electrode 904 or the reflector 906 may be connected to a ground.

In some implementations, the display device 900 can include one or more thin film encapsulation layers 917 over the inverted IMOD pixels. The one or more thin film encapsulation layers 917 are on the display side of the inverted IMOD pixels. The thin film encapsulation layers 917 can include the shell layer 912 and a sealing layer 914 formed over the shell layer 912. The thin film encapsulation layers 917 can hermetically seal each inverted IMOD 915 between the thin film encapsulation layers 917 and the substrate 902. In some implementations, the thin film encapsulation layers 917 include a transparent layer.

In some implementations, the shell layer 912 can serve as a structural layer for supporting the absorbing layer 910, with orifices for facilitating the etching of sacrificial layers in fabricating the IMOD 915. The sealing layer 914 can seal the shell layer 912. In some implementations, the shell layer 912 can be one of the thin film encapsulation layers 917 that is sealed with sealing layer 914.

In some implementations, an image from a display side of the display device 900 can be seen, for example, by the viewer 922. As illustrated in FIG. 9, the one or more thin film encapsulation layers 917 can be on the display side of the display device 900. Unlike some IMOD configurations where the viewer 922 sees the image through the substrate 902, the inverted IMOD configuration enables the image to be seen through a display side opposite the substrate 902. As such, structures below the reflective layer 906 or the absorbing layer 910 can be substantially non-transparent.

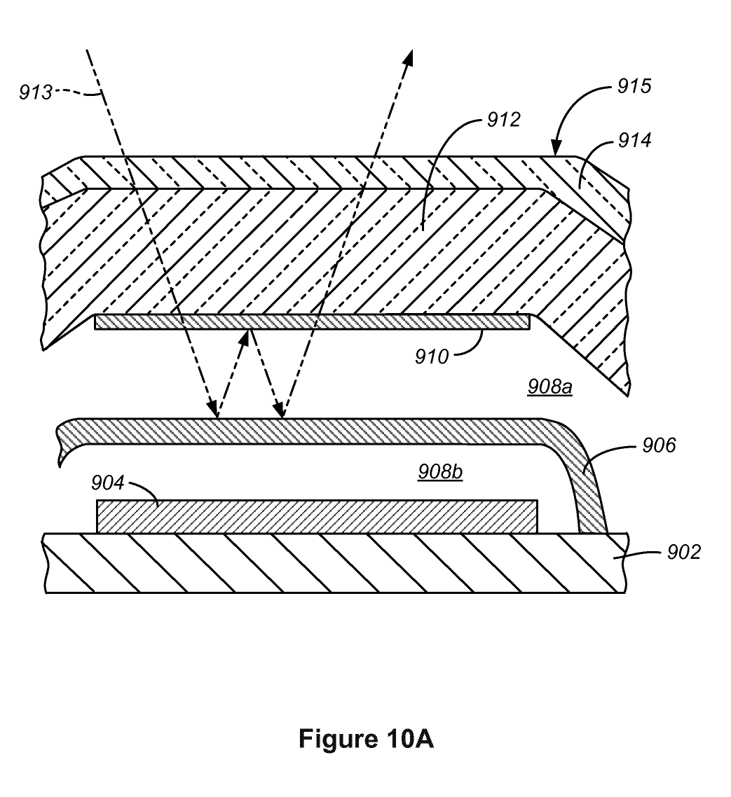

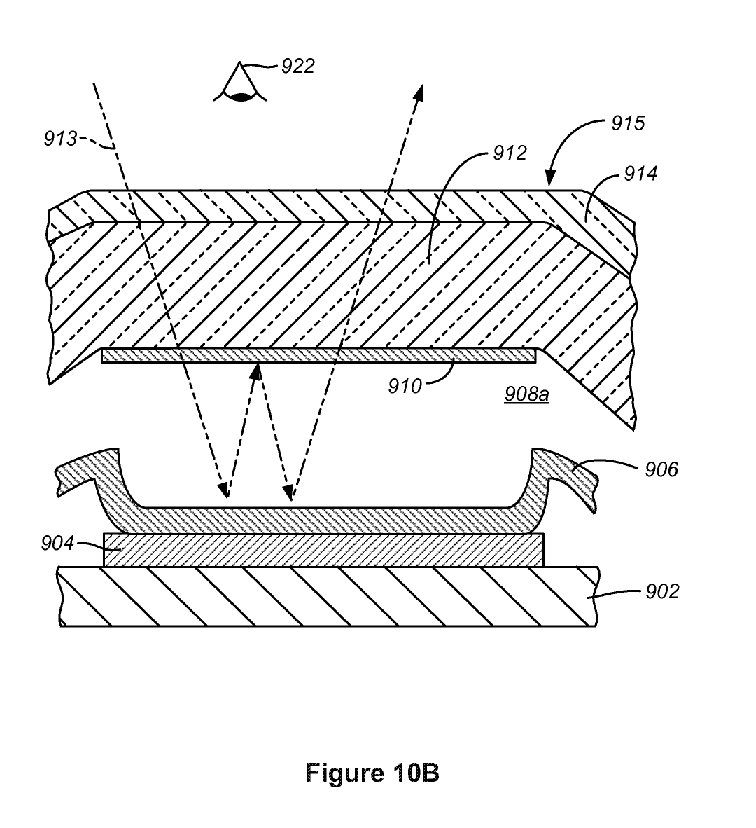

FIG. 10A shows an example of an enlarged cross-sectional side view of the display device of FIG. 9 in an unactuated state. In the unactuated state with no voltage applied, light 913 incident on the inverted IMOD 915 can be transmitted through the optical gap 908a and reflected off the reflective layer 906. In some implementations, the light 913 can travel through the optical gap 908a to maximize absorption at a given wavelength. The thickness of the optical gap 908a can be configured, for example, to maximize absorption at a relatively wide range of wavelengths. Hence, the light 913 reflected off the reflective layer 906 in the unactuated state can achieve a dark state appearance. Although illustrated as though reflective layer 906 and absorbing layer 910 are spaced apart, in some implementations, it is understood that the two layers may contact each other, or that the absorbing layer 910 may include an optical layer to enhance its optical performance that is formed between the absorbing layer and the reflective layer 906, and that the reflective layer 906 may be in contact with the optical layer.

FIG. 10B shows an example of an enlarged cross-sectional side view of the display device of FIG. 9 in an actuated state. The reflective layer 906 can be movable between the unactuated state and the actuated state. In the actuated state, when a voltage is applied, the reflective layer 906 can be displaced by electrostatic attraction towards the electrode 904. As a result, the distance between the absorbing layer 910 and the reflective layer 906 is altered. In a bistable IMOD, the reflective layer 906 can be configured to move between two different distances from the absorbing layer 910, for example a fully un-actuated position (as illustrated in FIG. 10A) and a fully actuated position (as illustrated in FIG. 10B). For example, the reflective layer 906 can be one distance in an actuated state and another distance in the unactuated state. In a multi-state IMOD, the reflective layer 906 can be configured to move to three or more distances from the absorbing layer 910, for example an unactuated state, a semi-actuated state, and a fully actuated state. In other words, the reflective layer 906 can be configured to move and stop at three or more different positions from the absorbing layer 910. In some implementations, the multi-state IMOD can be an analog IMOD with at least eight different positions. For example, the eight different positions can correspond to a reflection of eight different wavelength bands of visible light, such as white, black, and six other colors. When the reflective layer 906 is displaced towards the electrode 904, the size of the optical gap 908a changes so that the optical path length traveled by the light 913 reflected off the reflective layer 906 changes. The distance across the optical gap 908a can be configured so that the phase shift between light reflected off the movable reflective layer 906 and light reflected off the absorbing layer 910 maximizes constructive interference of a wavelength associated with a color, such as blue, green, or red light. In some implementations, the light 913 reflected off the reflective layer 906 can achieve a blue, green, or red color appearance.

The electrode 904 may include an optical stack over the substrate 902 and can include two or more sub-layers. In some implementations, the electrode 904 can include one or more electrically conductive materials for providing electrostatic operation of the display device 900. For example, the electrode 904 can be made of a metal or semiconductor with a desired electrical conductivity.

The reflective layer 906 can be positioned over the electrode 904. The reflective layer 906 can be supported above the substrate 902 by posts, or can be self-supporting. The reflective layer 906 can include one or more sub-layers. For example, the reflective layer 906 can include a reflective sub-layer, a support sub-layer, and/or a conductive sub-layer. In some implementations, the support sub-layer can be a dielectric sub-layer of, for example, SiON. The reflective sub-layer and the conductive sub-layer can include, for example, metallic materials such as aluminum-copper (AlCu) with about 0.5% Cu by weight. In other implementations, the reflective sub-layer can include other reflective metals such as silver (Ag), Cu, or nickel (Ni). A conductor above and below the dielectric support sub-layer can balance stresses and provide enhanced conduction. In some implementations, the reflective layer 906 can be a single layer. The total thickness of the reflective layer 906 can be between about 500 Å and about 5000 Å.

In some implementations, an air gap 908b exists between the electrode 904 and the reflective layer 906. The thickness of the air gap 908b can correspond to the thickness of a sacrificial layer deposited between the electrode 904 and the reflective layer 906, which can be removed by etching.

The absorbing layer 910 can be positioned above the reflective layer 906. In some implementations, the absorbing layer 910 can be attached to and/or supported by the shell layer 912 as illustrated in FIGS. 9, 10A and 10B. The absorbing layer 910 can include any number of materials that at least partially absorb light, including but not limited to Mo, Cr, Si, germanium (Ge), and MoCr. In general, the absorbing layer 910 includes a metallic material having a semi-reflective thickness. In some implementations, the thickness of the absorbing layer 910 can be between about 10 Å and about 100 Å.

The shell layer 912 can be positioned above the absorbing layer 910. The shell layer 912 can be formed of any number of different materials, such as transparent materials that can include aluminum oxide (Al₂O₃), SiO₂, spin-on glass, SiON, niobium oxide (Nb₂O₅), yttrium oxide (Y₂O₃), acrylic, polyimide, other similar materials, and combinations thereof. In some implementations, the thickness of the shell layer 912 may be between about 100 nm to about 20 μm, or about 1 μm to about 3 μm. In some implementations, the shell layer 912 can be formed by thick film techniques and be part of the structure of the IMOD 915. For example, the shell layer 912 may function to provide mechanical support for subsequent layers. In some implementations, the shell layer 912 provides mechanical support for the sealing layer 914. In some implementations, the shell layer 912 can be deposited by thin film techniques and be one of the layers of the thin film encapsulation layers 917.

In some implementations, the shell layer 912 may be substantially nonporous. When the shell layer 912 is substantially nonporous, liquids and/or gases cannot generally pass through the shell layer 912. For example, when the shell layer 912 is substantially nonporous, a sacrificial layer may not be removed by the diffusion of etchants or other chemicals through the shell layer 912.

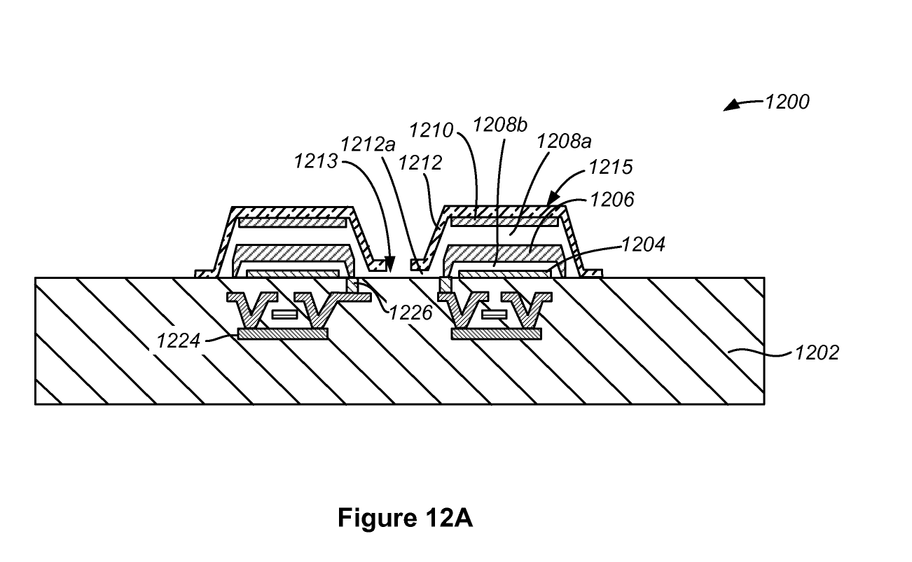

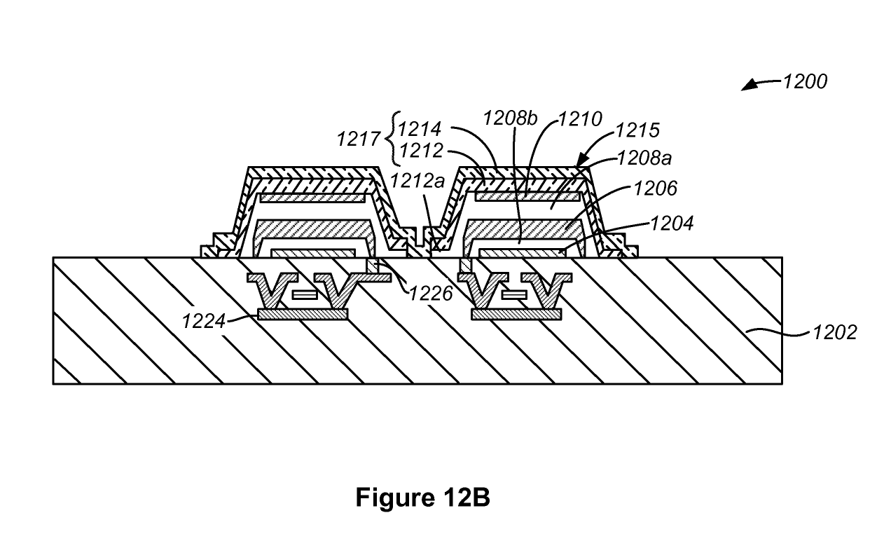

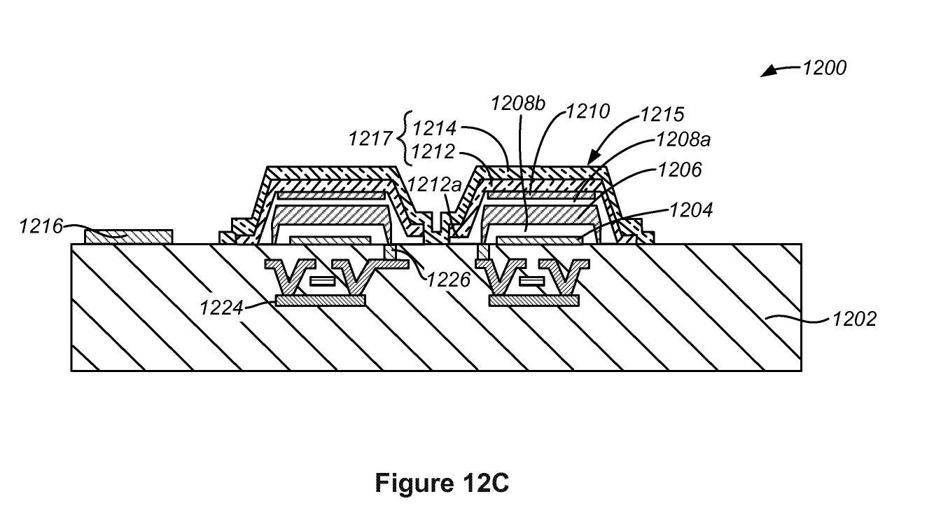

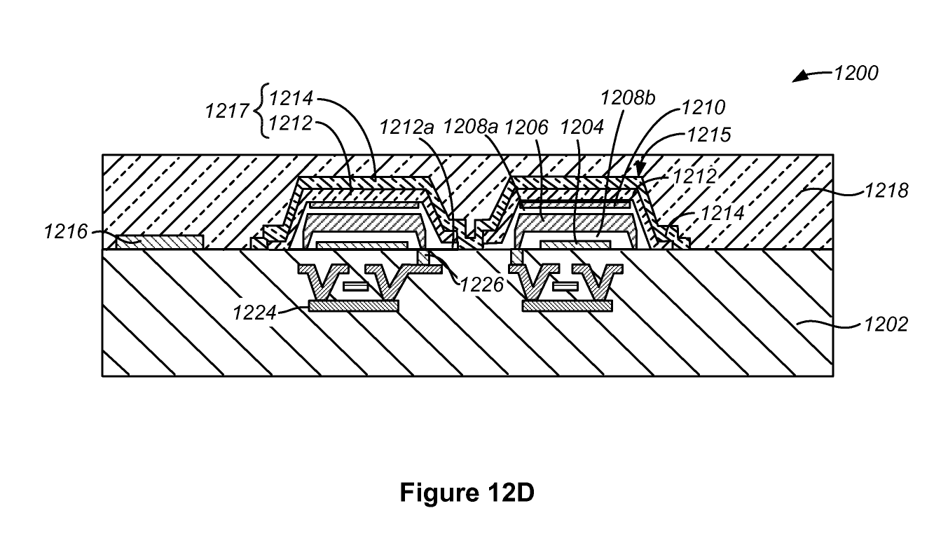

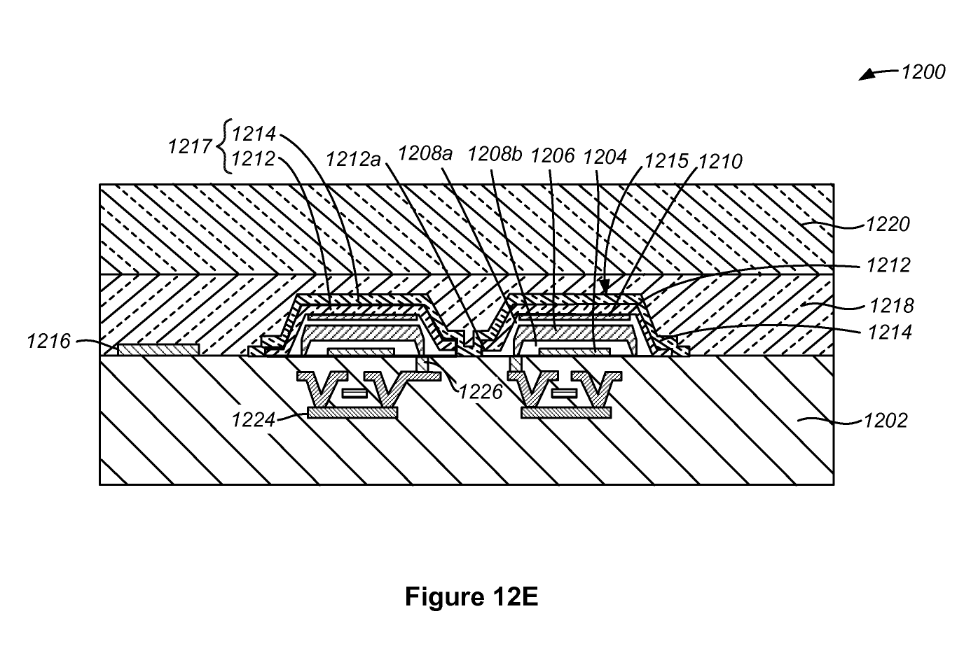

In some implementations, the shell layer 912 can include an etch hole 1213 (see FIG. 12A). The etch hole in FIG. 9 has been plugged up by the sealing layer 914. The etch hole can be connected to a cavity in the shell layer that includes the IMOD device via passage 912a, as illustrated in the example of FIG. 9. During fabrication, the etch hole and passage 912a may expose at least a sacrificial layer between the shell layer 912 and the movable reflective layer 906. Etching the sacrificial layer between the shell layer 912 and the movable reflective layer 906 removes the sacrificial layer so as to create the optical gap 908a. In addition, etching a sacrificial layer between the movable reflective layer 906 and the stationary electrode 904 can occur in the same etching process through passages not shown in the example in FIG. 9.

In some implementations, the shell layer 912 can include a plurality of etch holes or orifices (not shown). The orifices can allow one or more sacrificial layers under the shell layer 912 to be etched. The orifices can be subsequently plugged or sealed by the thin film encapsulation layers 917. In some implementations, the sealing layer 914 seals the passage 912a and/or the plurality of orifices in the shell layer 912. Thus, the thin film encapsulation layers 917 can form a hermetic seal for the IMOD between the thin film encapsulation layers 917 and the substrate 902.

In some implementations, the thin film encapsulation layers 917 can include the shell layer 912 and the sealing layer 914 that covers the shell layer 912, with the shell layer 912 disposed between the absorbing layer 910 and the sealing layer 914. The sealing layer 914 may also protect the IMOD from moisture and other contaminants.

The thin film encapsulation layers 917 can include any number of materials, including but not limited to spin-on glass, SiON, SiO₂, Al₂O₃, tantalum oxide (Ta₂O₅), titanium oxide (TiO₂), Nb₂O₅, Y₂O₃, acrylic, polyimide, dielectric materials, and other similar materials and combinations thereof. For example, the thin film encapsulation layers 917 can include a non-porous material capable of forming a hermetic seal that is also substantially optically transparent. According to various implementations, the thin film encapsulation layers 917 can be a single layer or can be multilayered. In some implementations, the total thickness of the thin film encapsulation layers 917 can be between about 1 μm and about 20 μm.

The thin film encapsulation layers 917 can also add rigidity and structural integrity to the encapsulated IMODs. Thus, the thin film encapsulation layers 917 can provide sufficient mechanical support for subsequent layers to be added over the thin film encapsulation layers 917. The thickness of the thin film encapsulation layers 917 can be balanced to be sufficiently thick to provide mechanical support yet sufficiently thin to provide optical transparency, for materials with optical absorption. Furthermore, thinner thin film encapsulation layers 917 also help reduce manufacturing cost.

In the example of FIG. 9, the thin film encapsulation layers 917 are conformal over the shell layer 912. The thin film encapsulation layers 917 can be anchored to the display device 900. In some implementations, the thin film encapsulation layers 917 can adhere to the substrate 902 between and along the edges of the inverted IMOD pixels.

In some implementations, the display device 900 can further include a sensor 916 directly formed on the substrate 902, as illustrated in the example of FIG. 9. Typically, a border region in the substrate 902 limits the space for providing the sensor 916 because the border region is used to place desiccant or a seal border for macro-encapsulation. Thin film encapsulation in display device 900 opens up space in the substrate 902 so that the sensor 916 can be formed on the substrate 902. The sensor 916 can be formed anywhere on the display device 900 concurrent with the fabrication of IMOD 915 or after formation of the thin film encapsulation layers 917. In some implementations, the sensor 916 can be formed on the substrate 902 in a process that is compatible with the process of manufacturing an inverted IMOD 915. In some implementations, the sensor 916 can be formed separate from and/or over one or more thin film encapsulation layers 917. Though the sensor 916 is not illustrated over the one or more thin film encapsulation layers 917, it is understood that the sensor 916 can be formed over the one or more thin film encapsulation layers 917. In some implementations, the sensor 916 formed over the one or more thin film encapsulation layers 917 can be formed in a separate process from the process of manufacturing the inverted IMOD 915. Hence, the sensor 916 can be formed after the inverted IMOD 915 is complete. The sensor 916 can include but is not limited to a light sensor, a pressure sensor, a humidity sensor, a proximity sensor, or a chemical sensor. The sensor 916 can be configured to receive input data to communicate to a processor (not shown) that is in electrical communication with the display device 900.

In some implementations, the display device 900 can include an optical adhesive layer 918 formed over the thin film encapsulation layers 917. The optical adhesive layer 918 can be configured to be an “optically matching” layer such that the index of refraction of the optical adhesive layer 918 “matches” the index of refraction of any layer above and/or below the optical adhesive layer 918. In one example, the optical adhesive layer 918 is above the thin film encapsulation layers 917. The optical adhesive layer 918 can optically match the thin film encapsulation layers 917 by having an index of refraction nₐ equal to the index of refraction of the thin film encapsulation layers 917, n_{b}, that is nₐ=n_{b}. This can reduce reflections at the interface between the two layers. In some cases, an optical mismatch may be desirable, and hence the indexes may be different. For example, the optical adhesive layer 918 is between the thin film encapsulation layers 917 and a viewing layer 920.

In addition to being optically matching, the optical adhesive layer 918 can also provide adhesion for subsequently deposited or attached layers. In some implementations, the optical adhesive layer 918 can include an adhesive layer. In some implementations, the adhesive layer can include a sheet adhesive. The sheet adhesive can be a single layer or a multi-layer sheet adhesive. In other implementations, the adhesive layer can include a liquid adhesive. Examples of liquid adhesives can include Vertak® from DuPont™ in Wilmington, Del., optically clear resins (OCRs), UV-curable resins, and thermally-curable resins.

The optical adhesive layer 918 can include multiple layers with different properties or functions. For example, the optical adhesive layer 918 can include a sheet adhesive with a diffuser. In another example, the optical adhesive layer 918 can include a multi-layer sheet adhesive with a diffuser and a conductive layer. The conductive layer can be an electromagnetic interference (EMI) shield over the IMOD 915, for example. The diffuser can be designed to scatter light to make an image appear more diffuse so as to enhance the color composition of a display. Having the diffuser over the IMOD 915 and near the IMOD 915 can increase the resolution of the display. In some implementations, the diffuser can be an adhesive having a thickness between about 25 μm and about 75 μm. In yet another example, the optical adhesive layer 918 can include an anti-reflective coating. Anti-reflection coatings can include one or more layers of dielectric material that are designed to reduce the amount of reflection from the optical adhesive layer 918.

In some implementations, the thickness of the optical adhesive layer 918 can be up to a millimeter, or up to 500 μm, for example between 175 μm to 300 μm, or between about 10 μm and about 75 μm. In some implementations, the optical adhesive layer 918 can be between about 25 μm and about 300 μm. As illustrated in the example of FIG. 9, the optical adhesive layer 918 can be substantially planar. Forming the planarized surface can include planarization processes such as mechanical polishing, chemical mechanical planarization, or a spin-coating process. The spin-coating process can include dispensing spin-on glass over the thin film encapsulation layers 917. In some implementations, the optical adhesive layer 918 can provide a substantially planarized surface for the attachment of a viewing layer 920.

In some implementations, the viewing layer 920 can be a functional layer over the thin film encapsulation layers 917. In some implementations, the optical adhesive layer 918 can be between the functional layer and the thin film encapsulation layers 917, as illustrated in the example in FIG. 9. However, it is understood that the optical adhesive layer 918 is optional and the functional layer can be directly over and in contact with the thin film encapsulation layers 917. While the optional optical adhesive layer 918 facilitates lamination of a functional layer over it, it is understood that the functional layer may be deposited or formed onto the thin film encapsulation layers 917 without the optical adhesive layer 918. The functional layer can include multiple layers with different properties or functions. For example, the functional layer can include a cover glass, a front light, a touch panel, an integrated touch sensor and front light, or any combination of the aforementioned. Any of the aforementioned can be static or integrated into one or more layers of plastic film, anti-reflection film, anti-glare film, anti-smudge film, and anti-splinter film.

In some implementations, the viewing layer 920 can be a transparent superstrate positioned over the optical adhesive layer 918. The transparent superstrate can be laminated on the optical adhesive layer 918. In some implementations, viewing layer 920 can be directly over and in contact with the tin film encapsulation layers 917. A transparent superstrate can be a polymer film or glass. In some implementations, the polymer film or glass of a transparent superstrate can be part of a front light. In some other implementations, the optical adhesive layer 918 can have a transparent layer such as spin-on glass that can be part of a front light. The front light can include a light guide, a light source for transmitting light into the light guide, and a plurality of light-turning features within the light guide.

In some implementations, the transparent superstrate can include a plastics film or glass with one or more touch sensors. The touch sensors can include touch sensor electrodes, such as thin conductive metal electrodes or indium tin oxide (ITO) electrodes. The one or more touch sensors can be integrated with a front light in the plastics film or glass of the transparent superstrate. The one or more touch sensors can be configured to receive input data to communicate to a processor that is in electrical communication with the display device 900.

In some implementations, the viewing layer 920 can include multiple layers such as a plastic film or a glass film with anti-reflective coating, diffuser, conductive material, and/or other desired components.

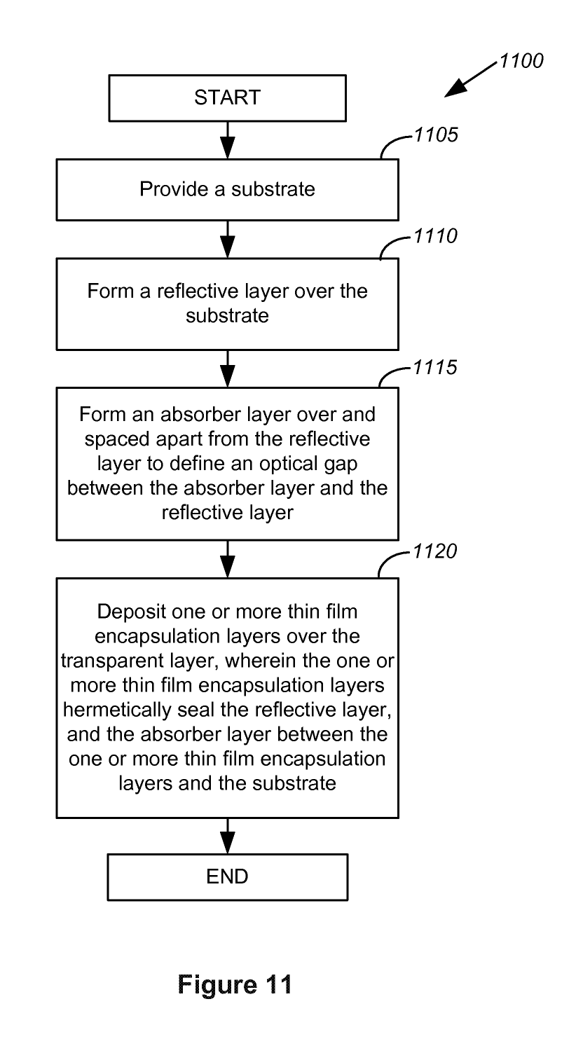

FIG. 11 shows an example of a flow diagram illustrating a method of manufacturing of a display device. Some of the blocks may be present in a process for manufacturing inverted IMODs, along with other blocks not shown in FIG. 11. For example, it will be understood that additional processes of depositing underlying or overlying layers, such as sacrificial layers, black mask layers, bussing layers, etc., may be present.

The process 1100 begins at block 1105 where a substrate is provided. As discussed earlier herein, the substrate may be transparent or non-transparent. In some implementations, providing the substrate can include forming an electrode by deposition of an electrode material, such as a metal or semiconductor with a desired electrical conductivity.

In some implementations, providing the substrate can include forming one or more TFTs on the substrate before forming the reflective layer over the substrate. The substrate can include a transparent material such as glass. Providing the substrate can further include forming routing lines and vias through the substrate and in electrical communication with the one or more TFTs. In some implementations, a substrate can be provided with one or more TFTs, routing lines, or vias formed on a planarization layer or a surface within the substrate.

The process 1100 continues at block 1110 where a reflective layer is formed over the substrate. The reflective layer can be supported above the substrate by posts, or can be self-supporting. A space can be present between the reflective layer and the substrate. In some implementations, the reflective layer can be formed by depositing a first sacrificial layer over the substrate and electrode, which can later be removed by an etchant. The first sacrificial layer can include but is not limited to fluorine-etchable materials such as Mo, tungsten (W), or amorphous silicon (a-Si). Alternatively, the first sacrificial layer can include a polymer or photoresist that can be etched by an oxygen plasma, an ashing process, or other technique. The first sacrificial layer can provide support for the reflective layer during fabrication of the reflective layer. The reflective layer can be deposited over the first sacrificial layer by any deposition techniques known in the art, such as physical vapor deposition (PVD), chemical vapor deposition (CVD), plasma-enhanced chemical vapor deposition (PECVD), atomic layer deposition (ALD), or spin-coating.

The process 1100 continues at block 1115 where an absorber layer can be formed over and spaced apart from the reflective layer to define an optical gap between the absorber layer and the reflective layer. Forming the absorber layer can include forming a second sacrificial layer above the reflective layer. In some implementations, the second sacrificial layer can provide a support for the absorber layer during fabrication of the absorber layer. In some implementations, the second sacrificial layer can include a polymer or photoresist. In other implementations, the second sacrificial layer can include a fluorine-etchable material, such as Mo, W, or a-Si. The absorber layer can be deposited over the second sacrificial layer using any deposition techniques known in the art. Removal of the first sacrificial layer and the second sacrificial layer can be accomplished using any suitable etching process, such as a wet etching or plasma etching process. For example, the etching process may include using an etchant such as XeF₂. After removal of the first sacrificial layer and the second sacrificial layer, a gap forms between the reflective layer and the electrode and an optical gap forms between the reflective layer and the absorber layer. In some implementations, the reflective layer can be movable across the gap and configured to electrostatically displace towards the electrode when a voltage is applied. In some implementations, the absorber layer can be movable across the optical gap and configured to electrostatically displace towards the reflective layer when a voltage is applied.

The process 1100 continues at block 1120 where one or more thin film encapsulation layers are deposited over the absorber layer. The one or more thin film encapsulation layers hermetically seal the reflective layer and the absorber layer between the one or more thin film encapsulation layers and the substrate. In some implementations, the one or more thin film encapsulation layers include a shell layer that is deposited over the first and second sacrificial layers. The one or more thin film encapsulation layers can also include additional layers conformally deposited over the shell layer. In some implementations, the one or more thin film encapsulation layers can be conformally deposited over the absorber layer. The one or more thin film encapsulation layers can be formed by a variety of deposition techniques as discussed earlier herein.

The one or more thin film encapsulation layers can include a transparent layer such as a shell layer. The shell layer can be porous or have an etch hole that allows for the removal of at least the second sacrificial layer. To anchor the shell layer to the substrate, the shell layer can be self-supporting or supported by posts. Additionally, after deposition, the shell layer can be treated by many different techniques. In some implementations, a monolayer of material or a layer of material may be deposited by an ALD process, such as an adhesion improvement layer that improves adhesion of subsequently deposited layers. In some implementations, treating the shell layer may include thermally treating the shell layer at an elevated temperature, exposing the shell layer to ultraviolet light, exposing the shell layer to a chemical reactant, or forming a self-assembled monolayer (SAM) on the shell layer. To form a hermetic seal, after the sacrificial layers are etched from below the shell layer, a sealing layer may be deposited to seal the shell layer and to plug any etch holes, orifices, or etch passages to leave a sealed thin film encapsulated cavity with inverted IMOD inside.

FIGS. 12A-12E show examples of cross-sectional views illustrating various stages of manufacturing a display device. The display device 1200 can include other components not shown in FIGS. 12A-12E, such as sacrificial layers, black mask layers, bussing layers, etc.

In FIG. 12A, an implementation of a display device 1200 with an array of EMS devices is provided. The display device 1200 can have a display side and a rear side opposite the display side. Two adjacent EMS devices such as IMODs can be fabricated on a substrate 1202 by thin film deposition and release processes, as discussed earlier herein. The substrate 1202 can be on the rear side of the display device 1200. The IMODs can be inverted IMOD pixels 1215 in an array of inverted IMOD pixels 1215. Each of the inverted IMOD pixels 1215 can include an electrode 1204 on the substrate 1202. The substrate 1202 can include one or more TFTs 1224 that can be in electrical communication with one or more of the inverted IMOD pixels 1215. For example, a TFT 1224 can connect from a backside of the substrate 1202 to an electrical component 1228, such as a bussing layer, through a via 1226. Alternatively, as described above, a layer of TFTs may be formed between the substrate and the inverted IMOD pixels 1215. Each of the inverted IMOD pixels 1215 can further include a reflective layer 1206 positioned above the electrode 1204, and an absorber layer 1210 positioned above the reflective layer 1206. Although reflective layer 1206 is illustrated as being self-supported to the substrate in the illustrated cross section, it is understood that in the illustrated cross sections of FIGS. 12A-12E, the reflective layer 1206 may be free of direct contact with any underlying or overlying supporting layers and may be supported by posts or bending regions in cross sections other than those illustrated. An optical gap 1208a can be defined between the absorber layer 1210 and the reflective layer 1206, and an air gap 1208b can be defined between the substrate 1202 and the electrode 1204. In some implementations, optical gap 1208a is in fluid communication with air gap 1208b. A shell layer 1212 can be positioned over the absorber layer 1210. In some implementations, the shell layer 1212 can encapsulate the absorber layer 1210, the reflective layer 1206, and the electrode 1204. Shell layer 1212 includes etch hole 1213 through which one or more sacrificial layers were etched previously.

In FIG. 12B, a sealing layer 1214 is deposited over the shell layer 1212 on the display side of the display device 1200 in the array of IMODs. Together, the shell layer 1212 and the sealing layer 1214 can form one or more thin film encapsulation layers 1217. The thin film encapsulation layers 1217 can provide a hermetic seal for the inverted IMOD 1215 between the thin film encapsulation layers 1217 and the substrate 1202. The thin film encapsulation layers 1217 that hermetically seal the inverted IMODs 1215 may improve the operational life of the display device 1200 compared to macro-encapsulated inverted IMODs. The sealing layer 1214 may be conformally deposited over the shell layer 1212, and can anchor the sealing layer 1214 to the substrate 1202 between and along the edges of the inverted IMOD pixels 1215. In some implementations, the deposition of the sealing layer 1214 can seal an etch hole 1213 (see FIG. 12A) in the shell layer 1212 thereby blocking an etching passage 1212a.

FIG. 12C illustrates forming a sensor 1216 on the substrate 1202. However, it is understood that the sensor 1216 can also be formed on the thin film encapsulation layers 1217. The sensor 1216 can be formed anywhere on the display device 1200 before or after the thin film encapsulation layers 1217 are formed. If the sensor 1216 is being fabricated with the IMOD pixels 1215, processes and materials may be similar to the IMOD pixels 1215. If the sensor 1216 is being fabricated on the thin film encapsulation layers 1217, the processes and materials could be any suitable processes and materials. In some implementations, the sensor 1216 can be an ambient light sensor. Other sensors can include a pressure sensor, a humidity sensor, a proximity sensor, or a chemical sensor.

FIG. 12D illustrates forming an optical adhesive layer 1218 over the thin film encapsulation layers 1217. In addition to forming over the thin film encapsulation layers 1217, the optical adhesive layer 1218 can form over the sensor 1216 as well as the substrate 1202.

In some implementations, optical adhesive layer 1218 can include an adhesive layer, such as a sheet adhesive or a cured liquid adhesive. Forming the optical adhesive layer 1218 can include dispensing the liquid adhesive or a roll-on process for the sheet adhesive. The optical adhesive layer 1218 can be configured to optically match to the thin film encapsulation layers 1217, as described earlier herein. In some implementations, forming the optical adhesive layer 1218 includes forming a planarized surface on the optical adhesive layer 1218, as illustrated in FIG. 12D. Forming the planarized surface can include a spin-coating process for a roll-on process, and the sheet adhesive can be soft to conform on the side facing the thin film encapsulation layers 1217 while planarized on the other surface. The spin-coating process can include dispensing spin-on glass over the thin film encapsulation layers 1217. As discussed earlier herein, the optical adhesive layer 1218 can include a diffuser, an anti-reflective coating, a conductive layer, and other desired functional components.

In some implementations, the optical adhesive layer 1218 can facilitate the subsequent lamination of a functional layer, such as a single layer integrating one or more touch sensors and/or front light. However, the optical adhesive layer 1218 is optional, and a functional layer may be deposited or formed on the thin film encapsulation layers 1217 without the optical adhesive layer 1218. For example, the functional layer can include a transparent material such as spin-on glass. One or more touch sensor electrodes can then be deposited on the spin-on glass, and the spin-on glass can be part of a front light. The touch sensor electrodes and front light can form an integrated touch and facet (ITF) glass for the display device 1200. FIG. 12D can illustrate an example of a completed display device 1200 for the inverted IMOD pixels 1215 with an ITF glass in the functional layer.

In FIG. 12E, a transparent superstrate 1220 can be laminated or otherwise attached to the optical adhesive layer 1218. The transparent superstrate 1220 can include a functional layer, as discussed above. The transparent superstrate 1220 can be a polymer film or glass. The transparent superstrate 1220 can include one or more touch sensor electrodes integrated in the polymer film or glass. The polymer film or glass can be part of a front light. In some implementations, the transparent superstrate can include a diffuser. FIG. 12E can illustrate an example of a completed display device 1200 for the inverted IMOD pixels.

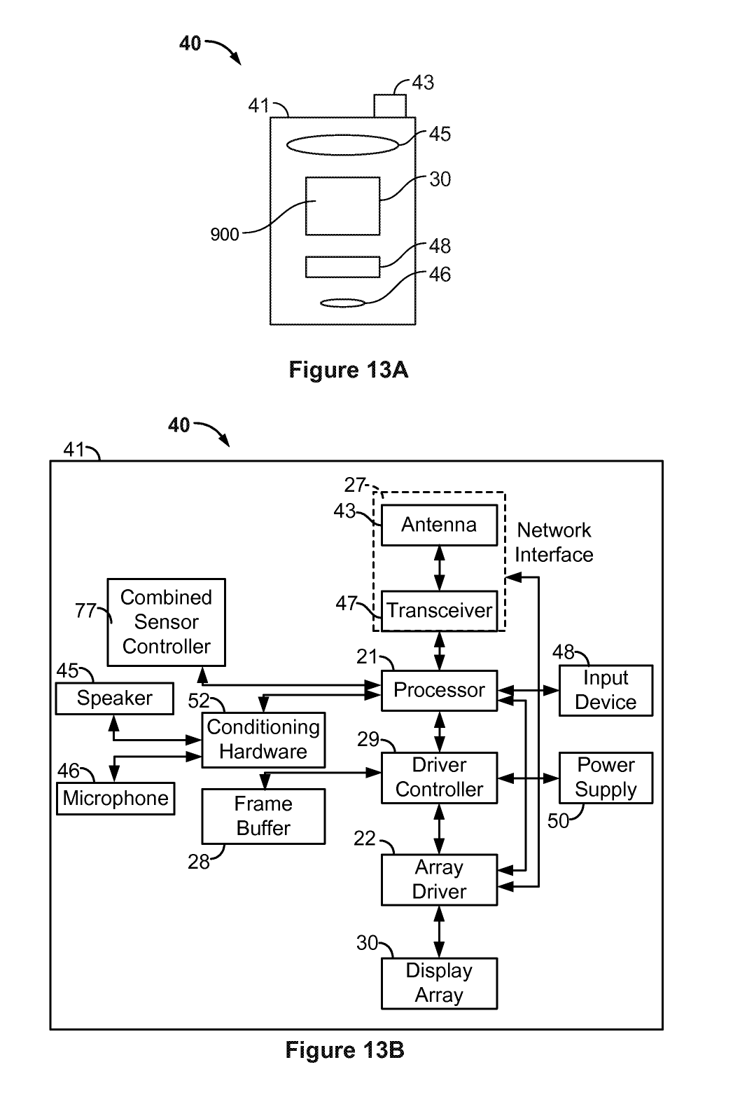

FIGS. 13A and 13B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display comprising:
a substrate;
an array of interferometric modulators (IMODs) formed on the substrate,
wherein each IMOD includes:
an absorbing layer separated from the substrate;
a reflective layer between the substrate and the absorbing layer; and
an optical gap between the absorbing layer and the reflective layer; and
one or more thin film encapsulation layers hermetically sealing each IMOD between the one or more thin film encapsulation layers and the substrate, the one or more thin film encapsulation layers including a transparent layer.

2. The display of claim 1, wherein the display has a display side for viewing the display and a rear side opposite the display side, wherein the one or more thin film encapsulation layers are on the display side of the array of IMODs.

3. The display of claim 1, wherein the substrate includes a plurality of thin film transistors.

4. The display of claim 3, wherein each IMOD is in electrical communication with one or more corresponding thin film transistors of the plurality of thin film transistors.

5. The display of claim 1, wherein the reflective layer is movable to three or more different distances from the absorbing layer.

6. The display of claim 5, wherein the reflective layer is movable to eight or more different distances from the absorbing layer.

7. The display of claim 1, further including an optical adhesive layer on the one or more thin film encapsulation layers.

8. The display of claim 7, wherein the optical adhesive layer includes a sheet adhesive or a cured liquid adhesive.

9. The display of claim 7, wherein the optical adhesive layer includes at least one of a diffuser or anti-reflective coating.

10. The display of claim 7, further including a transparent superstrate on the optical adhesive layer.

11. The display of claim 7, wherein the optical adhesive layer has a thickness between about 25 μm and about 300 μm.

12. The display of claim 1, further including a functional layer over the one or more thin film encapsulation layers.

13. The display of claim 12, wherein the functional layer includes one of a touch sensor, front light, and an integrated touch sensor and front light.

14. The display of claim 1, further including a sensor on the substrate or on the one or more thin film encapsulation layers.

15. The display of claim 1, wherein the one or more thin film encapsulation layers include at least one of a aluminum oxide, silicon oxide, spin-on glass, silicon oxynitride, niobium oxide, yttrium oxide, acrylic, or polyimide.

16. The display of claim 1, wherein the one or more thin film encapsulation layers have a thickness between about 1 μm and about 5 μm.

17. The display of claim 1, wherein the one or more thin film encapsulation layers include a shell layer and a sealing layer, wherein the shell layer is disposed between the absorbing layer of each IMOD and the sealing layer.

18. The display of claim 17, wherein the sealing layer includes an organic spin-on layer.

19. The display of claim 17, wherein the shell layer includes at least one of a silicon oxynitride, silicon oxide, silicon nitride, aluminum oxide, and aluminum nitride.

20. The display of claim 1, further comprising:
a processor that is configured to communicate with the display, the processor being configured to process image data; and
a memory device that is configured to communicate with the processor.

21. The display of claim 20, further comprising:
a driver circuit configured to send at least one signal to a thin film transistor in electrical communication with at least one IMOD in the array of IMODs.

22. The display of claim 21, further comprising:
a controller configured to send at least a portion of the image data to the driver circuit.

23. The display of claim 20, further comprising:
an image source module configured to send the image data to the processor, wherein the image source module includes at least one of a receiver, transceiver, and transmitter.

24. The display of claim 20, further comprising:
a sensor configured to receive input data and to communicate the input data to the processor.

25. A method of forming a display system, comprising:
providing a substrate;
forming a reflective layer over the substrate;
forming an absorber layer over and spaced apart from the reflective layer to define an optical gap between the absorber layer and the reflective layer; and
depositing one or more thin film encapsulation layers over the absorber layer, wherein the one or more thin film encapsulation layers hermetically seal the reflective layer and the absorber layer between the one or more thin film encapsulation layers and the substrate.

26. The method of claim 25, further including forming one or more thin film transistors on the substrate before forming the reflective layer over the substrate.

27. The method of claim 26, wherein the substrate includes glass.

28. The method of claim 25, wherein the one or more thin film encapsulation layers include a transparent layer.

29. The method of claim 25, further including forming a sensor on one of the substrate and the one or more thin film encapsulation layers.

30. The method of claim 29, wherein forming the sensor is performed after depositing the one or more thin film encapsulation layers.

31. The method of claim 25, further including forming an optical adhesive layer over the one or more thin film encapsulation layers.

32. The method of claim 25, further including forming a functional layer on the optical adhesive layer.

33. The method of claim 25, further including laminating a transparent superstrate on the optical adhesive layer.

34. A display system produced by the method as recited in claim 25.

35. A display system, comprising:
an array of interferometric modulators (IMODs) formed on a substrate, each IMOD comprising:
an absorbing layer separated from the substrate;
a reflective layer between the substrate and the absorbing layer; and
an optical gap defined between the absorbing layer and the reflective layer;
a functional layer over each IMOD in the array; and
means for encapsulating each IMOD in the array, the encapsulating means hermetically sealing each IMOD between the substrate and encapsulating means, the encapsulating means between the functional layer and each IMOD in the array, the encapsulating means including a means for transmitting light.

36. The display system of claim 35, wherein the encapsulating means has a thickness between about 1 μm and about 5 μm.

37. The display system of claim 35, further including a means for adhering the functional layer to the encapsulating means.
